(19) United States
(12) Patent Application Publication
(10) Pub. No.: US 2024/0290798 A1
(43) Pub. Date: Aug. 29, 2024

(54) MOTHER SUBSTRATE FOR DISPLAY PANEL AND METHOD OF MANUFACTURING DISPLAY DEVICE

(71) Applicant: Samsung Display Co., LTD., Yongin-si (KR)

(72) Inventors: HEECHANG YOON, Yongin-si (KR); SEUNGWOOK KWON, Yongin-si (KR); SANGTAE AHN, Yongin-si (KR); JINHO HYUN, Yongin-si (KR); SANGYEON HWANG, Yongin-si (KR); SEUNGYONG SONG, Yongin-si (KR); SEUNG-YEON CHAE, Yongin-si (KR)

(21) Appl. No.: 18/586,057

(22) Filed: Feb. 23, 2024

(30) Foreign Application Priority Data
Feb. 27, 2023 (KR) 10-2023-0026344

(51) Int. Cl. H01L 27/12

(52) U.S. Cl. CPC H01L 27/1244; H01L 27/1262

(57) ABSTRACT

A mother substrate for a display panel includes display panels disposed on a substrate, protective films disposed on the substrate and covering the display panels, and anti-peeling patterns disposed on the substrate and adjacent to the protective films, respectively.

This application claims priority to Korean Patent Application No. 10-2023-0026344, filed on Feb. 27, 2023, and all the benefits accruing therefrom under 35 U.S.C. § 119, the content of which in its entirety is herein incorporated by reference.

### BACKGROUND

### 1. Field

Embodiments of the invention relate generally to a mother substrate for a display panel and a method of manufacturing a display device.

### 2. Description of the Related Art

A display device typically includes a display panel, a functional layer, and a window. The display panel may display an image. The functional layer may be a touch panel for sensing a user's touch, a light path control layer for improving display quality of the display panel, or the like. The window may protect the display panel and the functional layer.

### SUMMARY

In a method of manufacturing the display device, a protective film for protecting the display panel may be adhered on the display panel. In this case, the protective film is desired to remain without being removed while the display device is being manufactured to increase the yield of the display device.

Embodiments provide a mother substrate for a display panel.

Embodiments provide a method of manufacturing a display device.

A mother substrate for a display panel according to an embodiment includes display panels disposed on a substrate, protective films disposed on the display panels and covering the display panels, respectively, and anti-peeling patterns disposed on the substrate and adjacent to the protective films, respectively.

In an embodiment, the protective films may include a first protective film and a second protective film adjacent to the first protective film, the anti-peeling patterns may include a first anti-peeling pattern and a second anti-peeling pattern, the first anti-peeling pattern may be adjacent to the first protective film and may be disposed between the first protective film and the second protective film, and the second anti-peeling pattern may be adjacent to the second protective film.

In an embodiment, a first distance between the first anti-peeling pattern and a first protective film may be less than a half of a distance between the first protective film and the second protective film.

In an embodiment, the first distance may be less than a second distance between the first anti-peeling pattern and the second protective film.

In an embodiment, the first distance may be in a range of about 200 micrometers (μm) to 1000 μm, and the second distance may be greater than about 1000 μm.

In an embodiment, a first height of each of the anti-peeling patterns may be in a range of about 30% to about 100% of a second height of each of the protective films.

In an embodiment, the first height may be in a range of about 30 μm to 100 μm.

In an embodiment, a width of each of the anti-peeling patterns may be in a range of about 3 millimeters (mm) to 10 mm.

In an embodiment, the mother substrate may further include an acid-resistant film disposed on the substrate and covering the protective films and the anti-peeling patterns.

In an embodiment, the acid-resistant film may include a base layer and an adhesive layer disposed under the base layer and contacting the protective films and the anti-peeling patterns. In such an embodiment, the adhesive layer may not be applied to an end of each of the protective films, wherein the end of each of the protective films is an end thereof adjacent to a corresponding one of the anti-peeling patterns.

In an embodiment, the protective films may be arranged along a first direction and a second direction perpendicular to the first direction when viewed in a thickness direction of the substrate, the acid-resistant film may be removed along the first direction, and the anti-peeling patterns may be adjacent to the protective films in a third direction opposite to the first direction.

In an embodiment, the protective films may be arranged along a first direction and a second direction perpendicular to the first direction when viewed in a thickness direction of the substrate, the acid-resistant film may be removed along a first diagonal direction between the first direction and the second direction, and the anti-peeling patterns may be adjacent to the protective films in a second diagonal direction opposite to the first diagonal direction.

In an embodiment, each of the anti-peeling patterns may include a first portion extending in the first direction and a second portion extending in the second direction and connected to the first portion.

In an embodiment, the protective films may be arranged along a first direction and a second direction perpendicular to the first direction when viewed in a thickness direction of the substrate, the acid-resistant film may be removed along a first diagonal direction and a third diagonal direction, where the first diagonal direction may be between the first direction and the second direction, and the third diagonal direction may be symmetrical to the first diagonal direction with the first direction as an axis of symmetry, and the anti-peeling patterns may be adjacent to the protective films in a second diagonal direction and a fourth diagonal direction, where the second diagonal direction may be opposite to the first diagonal direction, and the fourth diagonal direction may be opposite to the third diagonal direction.

In an embodiment, the protective films may be arranged along a first direction and a second direction perpendicular to the first direction when viewed in a thickness direction of the substrate, and the anti-peeling patterns may be adjacent to the protective films, respectively, and each of the anti-peeling patterns may surround a corresponding one of the protective films.

In an embodiment, the anti-peeling patterns may include a same material as the protective films.

A method of manufacturing a display device according to an embodiment may include forming display panels on a preliminary substrate, forming protective films covering the display panels on the preliminary substrate, and forming anti-peeling patterns adjacent to the protective films, respectively, on the preliminary substrate.

In an embodiment, the protective films and the anti-peeling patterns may be formed during a same process using a same material.

In an embodiment, the method may further include adhering an acid-resistant film on the preliminary substrate to cover the protective films and the anti-peeling patterns, forming a substrate by etching the preliminary substrate, removing the acid-resistant film, and removing the anti-peeling patterns.

In an embodiment, the anti-peeling patterns may be removed together with the acid-resistant film.

In embodiments of the invention, a mother substrate for a display panel may include protective films, anti-peeling patterns, and an acid-resistant film. In such embodiments, the protective films protect display panels, and the acid-resistant film may protect the display panels and the protective films. In such embodiments, the anti-peeling patterns may be adjacent to the protective films, respectively. In an embodiment, the anti-peeling patterns may be adjacent to the protective films in a second diagonal direction opposite to a first diagonal direction in which the acid-resistant film is removed.

In such embodiments, as the anti-peeling patterns are adjacent to the protective films, an adhesive layer of the acid-resistant film may not be applied or less applied to an end of each of the protective films adjacent to a corresponding one of the anti-peeling patterns. Accordingly, the adhesive force between the ends of the protective films and the acid-resistant film may be weakened, and the protective films may remain without being removed while the acid-resistant film is removed. Accordingly, the reliability of the protective films may be improved, and the yield of the mother substrate for the display panel may be improved.

In the method of manufacturing the display device according to embodiments of the invention, the anti-peeling patterns may be formed together with the protective films. Accordingly, a process of forming the anti-peeling patterns may be simplified. In such embodiments, the anti-peeling patterns may be removed together with the acid-resistant film. Accordingly, a process of removing the anti-peeling patterns may be simplified.

### BRIEF DESCRIPTION OF THE DRAWINGS

The accompanying drawings, which are included to provide a further understanding of the invention and are incorporated in and constitute a part of this specification, illustrate embodiments of the invention together with the description.

FIG. 1 is a plan view illustrating a mother substrate for a display panel according to an embodiment of the invention.

FIG. 2 is a cross-sectional view illustrating the mother substrate of FIG. 1.

FIG. 3 is a cross-sectional view illustrating a display panel included in the mother substrate of FIG. 1.

FIGS. 4, 5, 6, 7, 8, 9, 10, 11, 12, 13, 14, 15, 16, 17, and 18 are views illustrating a method of manufacturing a display device according to an embodiment of the invention.

FIG. 19 is an enlarged view of a stain line shown in FIG. 15.

FIG. 20 is a plan view illustrating a mother substrate for a display panel according to an alternative embodiment of the invention.

FIG. 21 is a plan view illustrating a mother substrate for a display panel according to another alternative embodiment of the invention.

FIG. 22 is a plan view illustrating a mother substrate for a display panel according to still another alternative embodiment of the invention.

FIG. 23 is a plan view illustrating a mother substrate for a display panel according to still another alternative embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,”“second,”“third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,”“component,”“region,”“layer” or “section” discussed below could be termed a second element, component, region, layer or section without departing from the teachings herein.

The terminology used herein is for the purpose of describing particular embodiments only and is not intended to be limiting. As used herein, “a”, “an,”“the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Illustrative, non-limiting embodiments will be more clearly understood from the following detailed description in conjunction with the accompanying drawings.

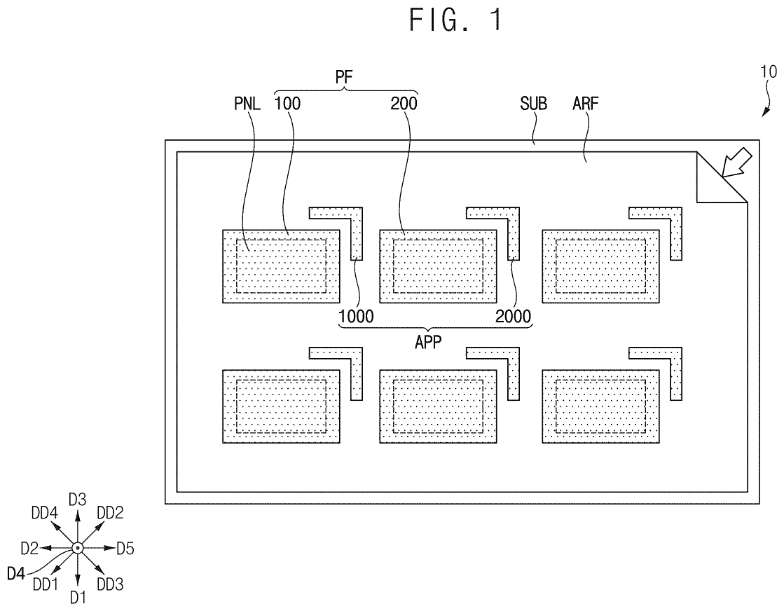

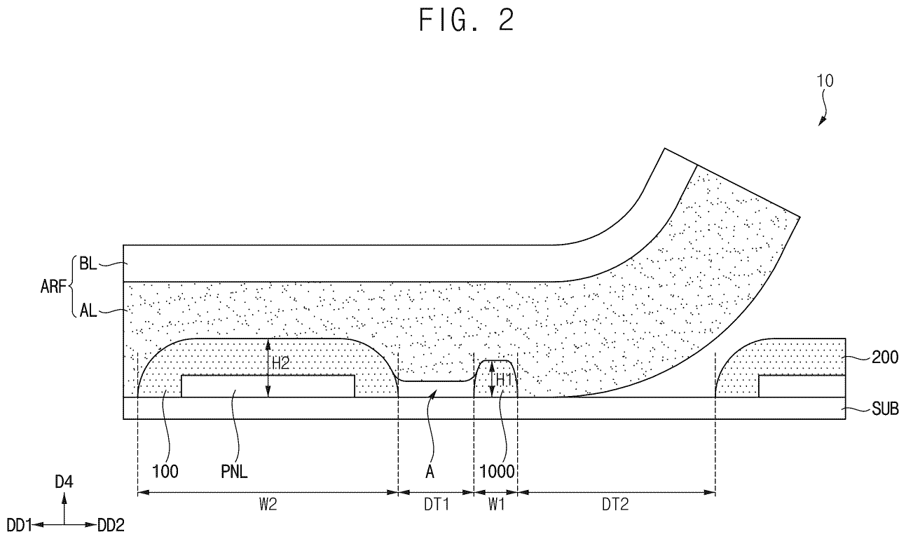

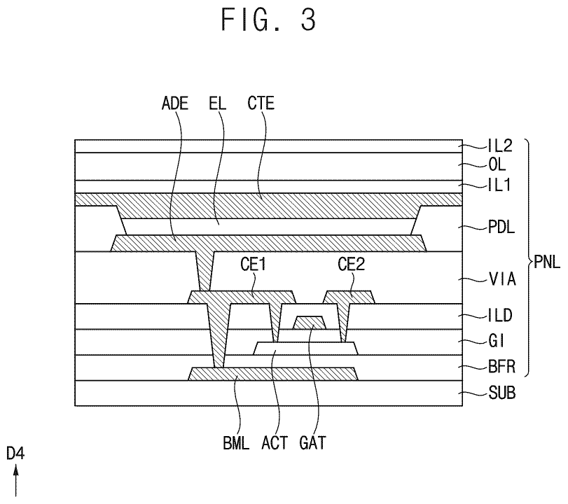

FIG. 1 is a plan view illustrating a mother substrate for a display panel according to an embodiment of the invention. FIG. 2 is a cross-sectional view illustrating the mother substrate of FIG. 1. FIG. 3 is a cross-sectional view illustrating a display panel included in the mother substrate of FIG. 1.

Referring to FIG. 1, a mother substrate 10 for a display panel according to an embodiment of the invention may include a substrate SUB, display panels PNL, protective films PF, anti-peeling patterns APP, and an acid-resistant film ARF.

In an embodiment, examples of materials that can be used as the substrate SUB may include ultra thin glass (UTG), glass, quartz, plastic, or the like. These may be used alone or in combination with each other. In addition, the substrate SUB may be composed of (or defined by) a single layer or multiple layers in combination with each other.

The display panels PNL may be disposed on the substrate SUB. Each of the display panels PNL may constitute one cell, and the structure of each of the display panels PNL will be described later with reference to FIG. 3.

The protective films PF may protect the display panels PNL. In an embodiment, the protective films PF may be disposed on the substrate SUB and may cover the display panels PNL, respectively. In an embodiment, for example, each of the protective films PF may entirely cover an upper surface of each of the display panels PNL, and ends of the protective films PF may contact the substrate SUB.

In an embodiment, as shown in FIG. 1, each of the protective films PF may have a rectangular shape, but the invention is not limited thereto. The shape of each of the protective films PF may be appropriately set or variously modified in consideration of a shape of each of the display panels PNL.

In an embodiment, the protective films PF may be arranged along a first direction D1 and a second direction D2 perpendicular to the first direction D1 when viewed in a plan view or when viewed in the fourth direction D4. In such an embodiment, the protective films PF may be arranged in a matrix form.

In an embodiment, the protective films PF may include a first protective film 100 and a second protective film 200. The second protective film 200 may be adjacent to the first protective film 100. In such an embodiment, the first protective film 100 may cover a first display panel among the display panels PNL, and the second protective film 200 may cover a second display panel adjacent to the first display panel.

In an embodiment, the protective films PF may include a photocurable resin. The photocurable resin may be a polymer resin, a hardness of which is increased by being cured by light such as ultraviolet rays.

The anti-peeling patterns APP may effectively prevent the protective films PF from being peeled off. The anti-peeling patterns APP may be disposed on the substrate SUB. In an embodiment, the anti-peeling patterns APP may be adjacent to the protective films PF, respectively. In such an embodiment, the anti-peeling patterns APP may be adjacent to the protective films PF in a direction corresponding to a direction in which the acid-resistant film ARF is removed. In an embodiment, for example, where the direction in which the acid-resistant film ARF is removed is a first diagonal direction DD1, the anti-peeling patterns APP may be adjacent to the protective films PF in a second diagonal direction DD2 opposite to the first diagonal direction DD1, respectively.

In an embodiment, each of the anti-peeling patterns APP may include a first portion and a second portion. The first portion may extend in the first direction D1. The second part may extend in the second direction D2 and may be connected to the first portion.

In an embodiment, for example, the number of the anti-peeling patterns APP may be substantially the same as the number of the protective films PF, and the anti-peeling patterns APP may be formed or provided for each of the protective films PF.

In an embodiment, the anti-peeling patterns APP may include a first anti-peeling pattern 1000 and a second anti-peeling pattern 2000. The first anti-peeling pattern 1000 may be adjacent to the first protective film 100, and the second anti-peeling pattern 2000 may be adjacent to the second protective film 200. In such an embodiment, where the first protective film 100 and the second protective film 200 are adjacent to each other, the first anti-peeling pattern 1000 may be formed between the first protective film 100 and the second protective film 200.

In an embodiment, the anti-peeling patterns APP may include a photocurable resin. The photocurable resin may be a polymer resin, a hardness of which is increased by being cured by light such as ultraviolet rays.

In an embodiment, the protective films PF and the anti-peeling patterns APP may include a same material as each other. In an embodiment, for example, the protective films PF and the anti-peeling patterns APP may be formed together.

The acid-resistant film ARF may be adhered on the protective films PF, and may protect the protective films PF and the display panels PNL from the hydrofluoric acid solution. In an embodiment, the acid-resistant film ARF may be disposed on the substrate SUB and may cover the protective films PF and the anti-peeling patterns APP.

Referring to FIG. 2, in an embodiment, the acid-resistant film ARF may include a base layer BL and an adhesive layer AL.

The base layer BL may protect the protective films PF and the display panels PNL from a hydrofluoric acid solution. In an embodiment, the base layer BL may include a polymer resin. In an embodiment, for example, the base layer BL may include at least one selected from polyvinylchloride, polyethersulfone, polyacrylate, polyetherimide, polyethylene naphthalate, polyethylene terephthalate, polyethylene terephthalate, polyphenylene sulfide, polyarylate, polyimide, polycarbonate, and cellulose acetate propionate.

The adhesive layer AL may adhere the base layer BL to the protective films PF and the substrate SUB. In an embodiment, the adhesive layer AL may be disposed under the base layer BL and may contact the protective films PF and the anti-peeling patterns APP. The adhesive layer AL may include an adhesive, for example, a pressure sensitive adhesive, an optically clear adhesive, or an optically clear resin.

As shown in FIGS. 1 and 2, a first diagonal direction DD1 between the first direction D1 and the second direction D2, a second diagonal direction DD2 opposite to the first diagonal direction DD1, and a fourth direction D4 perpendicular to the first and second directions D1 and D2 may be defined, and the acid-resistant film ARF may be removed along the first diagonal direction DD1. Here, the fourth direction D4 may be a thickness direction of the substrate SUB.

In an embodiment, as shown in FIG. 1, the anti-peeling patterns APP may be adjacent to the protective films PF in the second diagonal direction DD2. In an embodiment, for example, the first anti-peeling pattern 1000 may be adjacent to the first protective film 100 in the second diagonal direction DD2, and the second anti-peeling pattern 2000 may be adjacent to the second protective film 200 in the second diagonal direction DD2.

In an embodiment, a first distance DT1 between the first anti-peeling pattern 1000 and the first protective film 100 may be less than a half of a distance between the first protective film 100 and the second protective film 200. In an embodiment, for example, the first distance DT1 may be less than a second distance DT2 between the first anti-peeling pattern 1000 and the second protective film 200.

In an embodiment, for example, the first distance DT1 may be in a range of about 200 micrometers (μm) to 1000 μm, and the second distance DT2 may be greater than about 1000 μm. If the first distance DT1 is less than about 200 μm, a margin distance between the first anti-peeling pattern 1000 and the first protective film 100 may not be secured. If the first distance DT1 is greater than about 1000 μm, the adhesive layer AL may be applied to an end of the first protective film 100.

In an embodiment, a first height H1 of the first anti-peeling pattern 1000 may be less than or equal to a second height H2 of the first protective film 100. Here, a height of an element on the substrate SUB may be defined as a distance from an upper surface of the substrate SUB to an uppermost surface of the element.

In an embodiment, for example, the first height H1 may be in a range of about 30% to about 100% of the second height H2. In an embodiment, the first height H1 may be in a range of about 30 μm to 100 μm, and the second height H2 may be about 100 μm. If the first height H1 is less than about 30% of the second height H2, the adhesive layer AL may be applied to an end of the first protective film 100. If the first height H1 is greater than about 100% of the second height H2, due to the spreadability of the resin forming the first anti-peeling pattern 1000, the first anti-peeling pattern 1000 and the first protective film 100 may contact each other during a manufacturing process.

In an embodiment, a first width W1 of the first anti-peeling pattern 1000 may be less than a second width W2 of the first protective film 100.

In an embodiment, for example, the first width W1 may be in a range of about 3 millimeters (mm) to about 10 mm. If the first width W1 is less than about 3 mm, the first anti-peeling pattern 1000 may not be sufficiently formed. If the first width W1 is greater than about 10 mm, the margin area of the mother substrate 10 for the display panel may not be secured.

However, the first distance DT1, the second distance DT2, the first height H1, the second height H2, the first width W1, and the second width W2 may be appropriately set or variously modified as desired. In embodiments, for example, the first distance DT1, the second distance DT2, the first height H1, the second height H2, the first width W1, and the second width W2 may be appropriately set or variously modified in consideration of the size of the mother substrate 10, the number of the display panel PNL, the distance among the display panels PNL, the distance among the protective films PF, or the adhesive force of the acid-resistance film ARF.

The mother substrate 10 for the display panel may include the protective films PF, the anti-peeling patterns APP, and the acid-resistant film ARF. The protective films PF may protect the display panels PNL, and the acid-resistant film ARF may protect the display panels PNL and the protective films PF. The anti-peeling patterns APP may be adjacent to the protective films PF, respectively. In an embodiment, for example, the anti-peeling patterns APP may be adjacent to the protective films PF in the second diagonal direction DD2 opposite to the first diagonal direction DD1 in which the acid-resistant film ARF is removed.

In such an embodiment, as the anti-peeling patterns APP are adjacent to the protective films PF, the adhesive layer AL may not be applied or less applied to an end area A adjacent to each of the protective films PF adjacent to each of the anti-peeling patterns APP. Accordingly, the adhesive strength between the end of the protective films PF and the acid-resistant film ARF may be weakened, and while the acid-resistant film ARF is removed, the protective films PF may not be removed and may remain. Accordingly, the reliability of the protective films PF may be improved, and the yield of the mother substrate 10 for the display panel may be improved.

Referring to FIG. 3, each of the display panels PNL may include a lower metal pattern BML, a buffer layer BFR, an active pattern ACT, a gate insulating layer GI, gate electrodes GAT, an interlayer insulating layer ILD, first and second connection electrodes CE1 and CE2, a via layer VIA, a pixel electrode ADE, a pixel defining layer PDL, an emission layer EL, a common electrode CTE, a first inorganic layer IL1, an organic layer OL, and a second inorganic layer IL2.

The lower metal pattern BML may be disposed on the substrate SUB. In an embodiment, the lower metal pattern BML may include or be formed of a metal, an alloy, a conductive metal oxide, a transparent conductive material, or the like. Examples of materials that can be used as the lower metal pattern BML may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. In addition, the lower metal pattern BML may be formed as (or defined by) a single layer or as multiple layers in combination with each other.

The buffer layer BFR may be disposed on the substrate SUB and may cover the lower metal pattern BML. In an embodiment, the buffer layer BFR may include or be formed of an inorganic insulating material. Examples of materials that can be used as the inorganic insulating material may include silicon oxide, silicon nitride, or silicon oxynitride. These may be used alone or in combination with each other. The buffer layer BFR may effectively prevent diffusion of metal atoms or atoms or impurities from the substrate SUB into the active pattern ACT. In addition, the buffer layer BFR may control a heat supply rate during a crystallization process for forming the active pattern ACT.

The active pattern ACT may be disposed on the buffer layer BFR. In an embodiment, the active pattern ACT may include or be formed of a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may include InGaZnO (IGZO) or InSnZnO (ITZO). In addition, the oxide semiconductor material may further include indium (In), gallium (Ga), tin (Sn), zirconium (Zr), vanadium (V), hafnium (Hf), cadmium (Cd), germanium (Ge), chromium (Cr), titanium (Ti), or zinc (Zn), for example. These may be used alone or in combination with each other.

The gate insulating layer GI may cover the active pattern ACT and may be disposed on the buffer layer BFR. In an embodiment, the gate insulating layer GI may be formed of an insulating material. Examples of an insulating material that can be used as the gate insulating layer GI may include silicon oxide, silicon nitride, or silicon oxynitride. These may be used alone or in combination with each other.

The gate electrode GAT may be disposed on the gate insulating layer GI. In an embodiment, the gate electrode GAT may include or be formed of metal, alloy, conductive metal oxide, transparent conductive material, or the like. Examples of materials that can be used for the gate electrode GAT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The interlayer insulating layer ILD may be disposed on the buffer layer BFR. The interlayer insulating layer ILD may cover the gate electrode GAT. In an embodiment, the interlayer insulating layer ILD may include or be formed of an insulating material. Examples of insulating materials that can be used as the interlayer insulating layer ILD may include silicon oxide, silicon nitride, or silicon oxynitride. These may be used alone or in combination with each other.

The first and second connection electrodes CE1 and CE2 may be disposed on the interlayer insulating layer ILD. In an embodiment, the first and second connection electrodes CE1 and CE2 may be formed of metal, alloy, conductive metal oxide, transparent conductive material, or the like. Examples of materials that can be used as the first and second connection electrodes CE1 and CE2 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The first connection electrode CE1 may contact the lower metal pattern BML and the active pattern ACT, and the second connection electrode CE2 may contact the active pattern ACT.

The via layer VIA may cover the first and second connection electrodes CE1 and CE2 and may be disposed on the interlayer insulating layer ILD. In an embodiment, the via layer VIA may include or be formed of an organic material. Examples of organic materials that can be used for the via layer VIA may include photoresist, polyacrylic resin, polyimide resin, or acrylic resin. These may be used alone or in combination with each other.

The pixel electrode ADE may be disposed on the via layer VIA. In an embodiment, the pixel electrode ADE may include or be formed of metal, alloy, conductive metal oxide, transparent conductive material, or the like. Examples of materials that can be used as the pixel electrode PXE may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The pixel defining layer PDL may be disposed on the pixel electrode ADE and may cover an end of the pixel electrode ADE. In an embodiment, the pixel defining layer PDL may include or be formed of an organic material. Examples of organic materials that can be used as the pixel defining layer PDL may include photoresist, polyacrylic resin, polyimide resin, or acrylic resin. These may be used alone or in combination with each other.

The emission layer EL may be disposed on the pixel electrode ADE. The common electrode CTE may be disposed on the emission layer EL.

The first inorganic layer IL1 may be disposed on the common electrode CTE. In an embodiment, the first inorganic layer IL1 may include or be formed of an inorganic material. Examples of inorganic materials that can be used as the first inorganic layer IL1 may include silicon oxide, silicon nitride, or silicon oxynitride. These may be used alone or in combination with each other.

The organic layer OL may be disposed on the first inorganic layer IL1. In an embodiment, the organic layer OL may include or be formed of an organic material. Examples of organic materials that can be used as the organic layer OL may include photoresist, polyacrylic resin, polyimide resin, or acrylic resin. These may be used alone or in combination with each other.

The second inorganic layer IL2 may be disposed on the organic layer OL. In an embodiment, the second inorganic layer IL2 may include or be formed of an inorganic material. Examples of inorganic materials that can be used as the second inorganic layer IL2 may include silicon oxide, silicon nitride, or silicon oxynitride. These may be used alone or in combination with each other.

However, the structure of each of the display panels PNL is not limited to the structure shown in FIG. 3, and various known display panels PNL may be applied to the mother substrate 10 for the display panel according to an embodiment of the invention. In an alternative embodiment, for example, the lower metal pattern BML may be omitted or an additional connection electrode may be further provided or formed between the first connection electrode CE1 and the pixel electrode ADE.

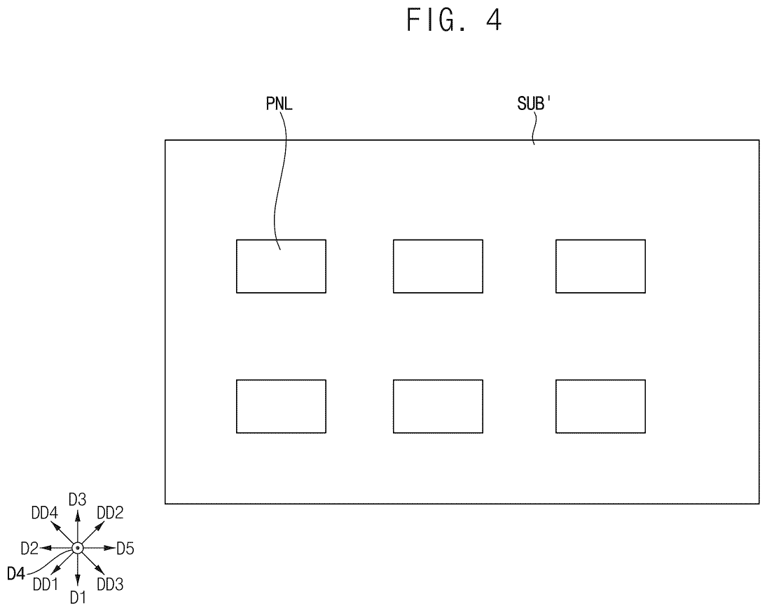

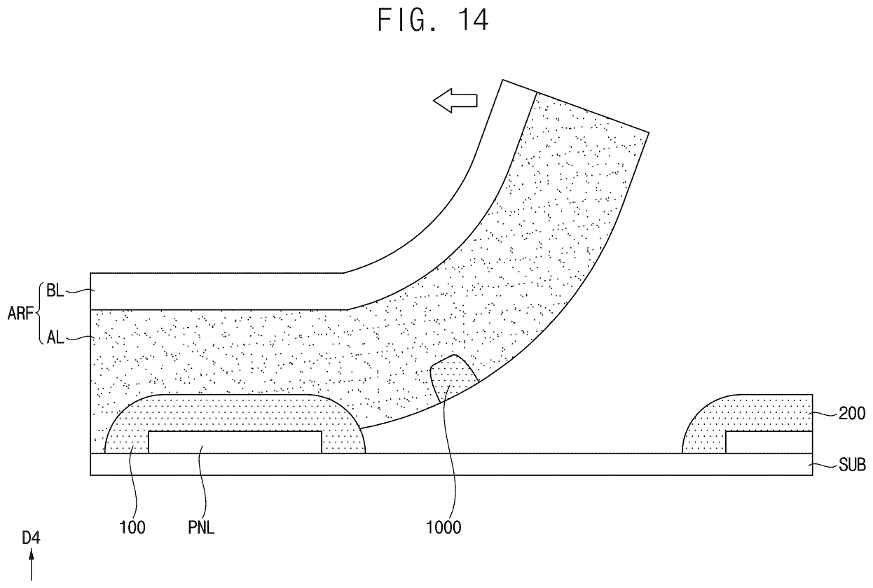

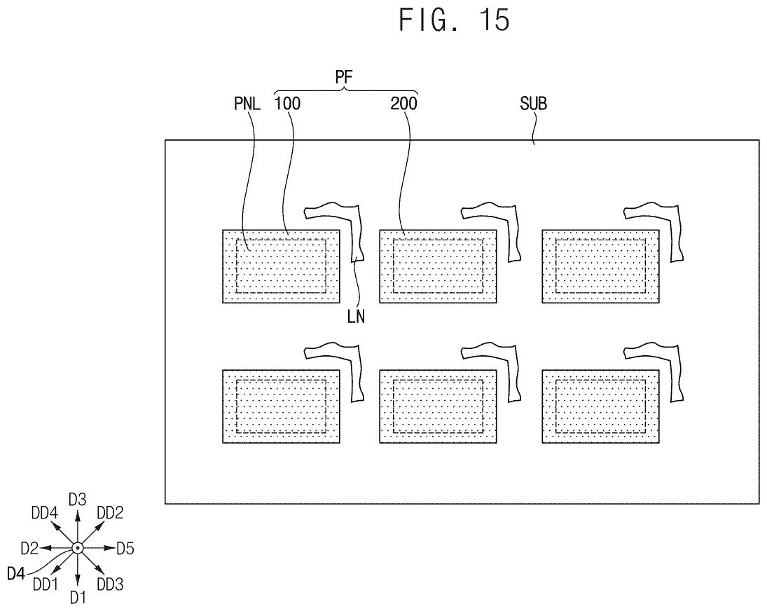

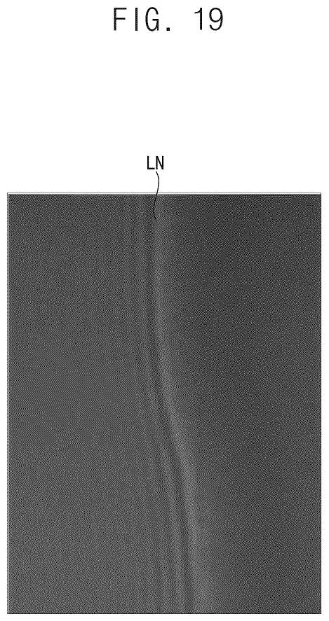

FIGS. 4, 5, 6, 7, 8, 9, 10, 11, 12, 13, 14, 15, 16, 17, and 18 are views illustrating a method of manufacturing a display device according to an embodiment of the invention. FIG. 19 is an enlarged view of a stain line shown in FIG. 15.

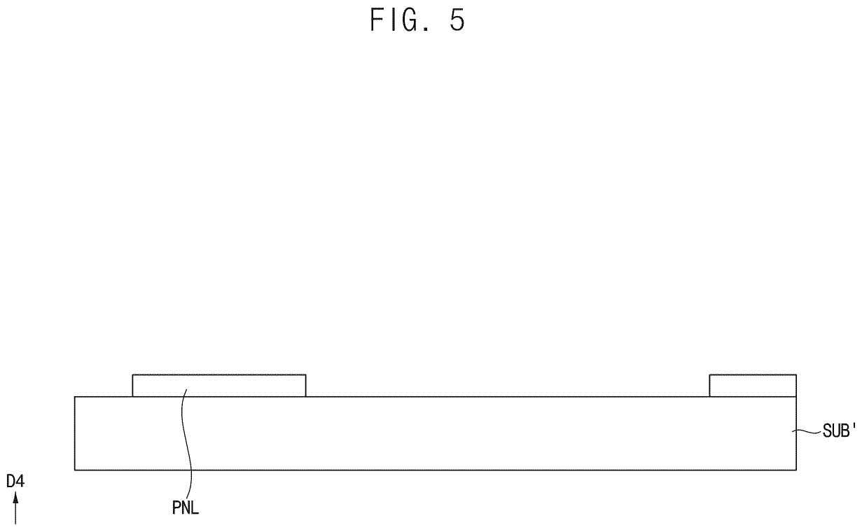

Referring to FIGS. 4 and 5, display panels PNL may be formed on a preliminary substrate SUB′. The preliminary substrate SUB′ may be the substrate SUB described above with reference to FIG. 1 or a substrate SUB before being etched. The preliminary substrate SUB′ may support the display panels PNL and may move the mother substrate 10 for the display panel during a manufacturing process of the display device. Each of the display panels PNL may correspond to the display panel described above with reference to FIG. 3.

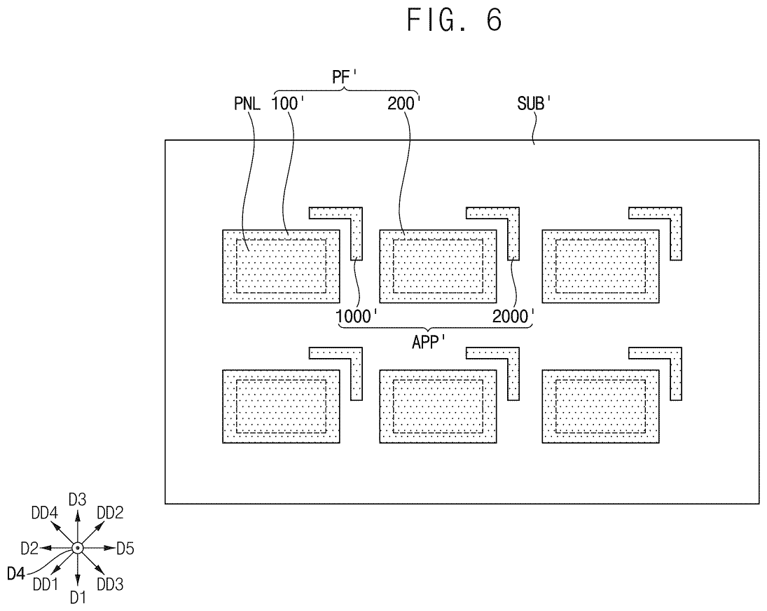

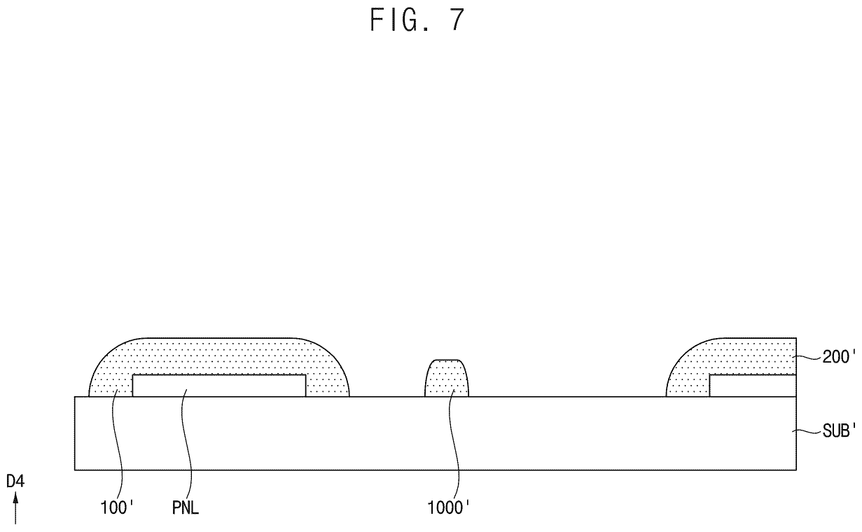

Referring to FIGS. 6 and 7, preliminary protective films PF′ and preliminary anti-peeling patterns APP′ may be formed on the preliminary substrate SUB′. The preliminary protective films PF′ may be the protective films PF before curing, and the preliminary anti-peeling patterns APP′ may be the anti-peeling patterns APP before curing.

In an embodiment, for example, the preliminary protective films PF′ may cover the display panels PNL, respectively, and the preliminary anti-peeling patterns APP′ may be adjacent to the preliminary protective films PF′. In an embodiment, the preliminary protective films PF′ and the preliminary anti-peeling patterns APP′ may be formed together, e.g., during a same process using a same material.

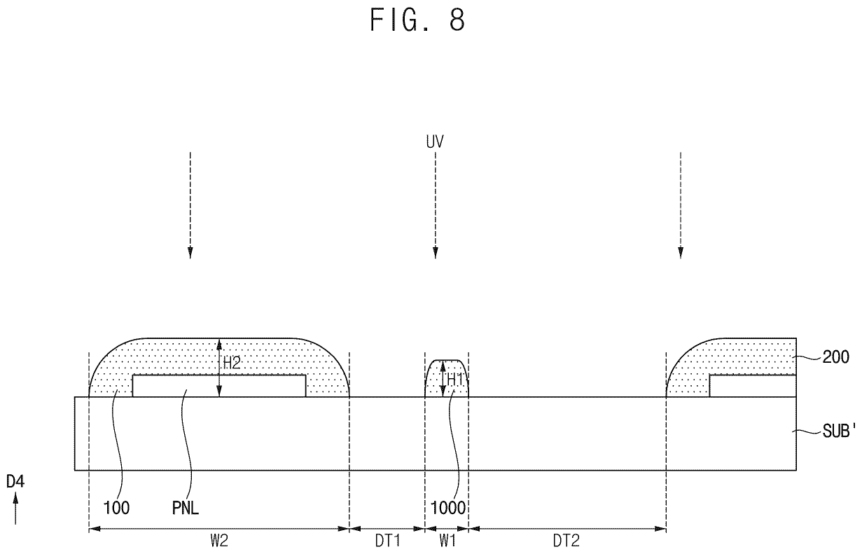

Referring to FIG. 8, the protective films PF and the anti-peeling patterns APP may be formed on the preliminary substrate SUB′. In an embodiment, for example, the protective films PF and the anti-peeling patterns APP may be formed by curing the preliminary protective films PF′ and the preliminary anti-peeing patterns APP′ with ultraviolet (UV).

In an embodiment, for example, the protective films PF may cover the display panels PNL, and the anti-peeling patterns APP may be adjacent to the protective films PF, respectively. In an embodiment, the protective films PF and the anti-peeling patterns APP may be formed together.

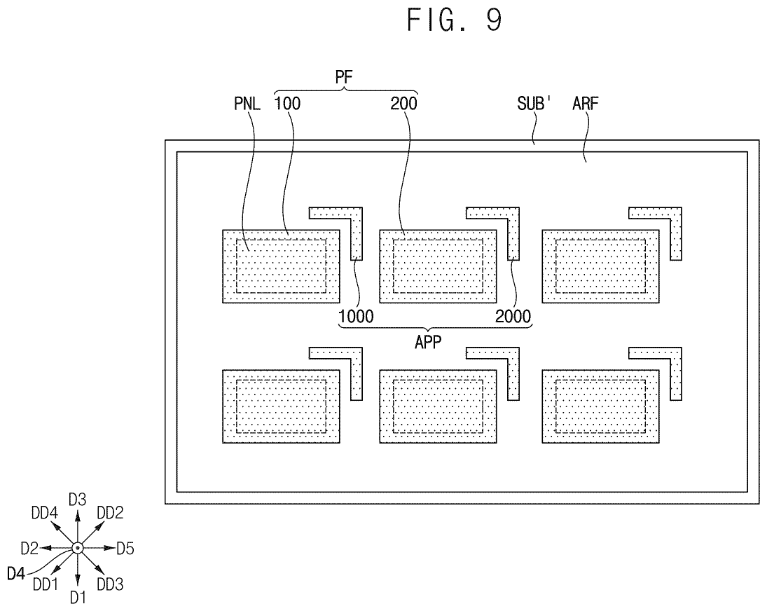

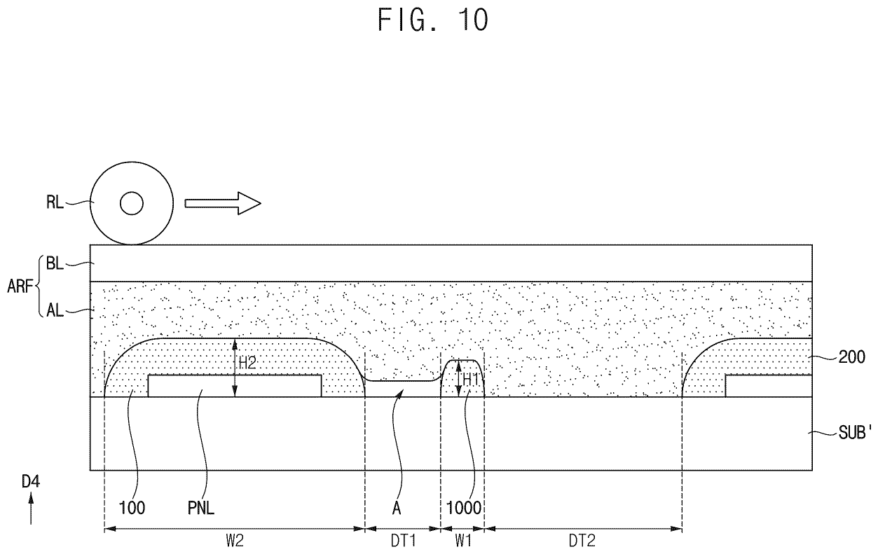

Referring to FIGS. 9 and 10, the acid-resistant film ARF may be adhered to the preliminary substrate SUB′. The acid-resistant film ARF may cover the protective films PF and the anti-peeling patterns APP. In an embodiment, the acid-resistant film ARF may be adhered while being pressed at a pressure in a range of about 1 kilogram force per square centimeter (kg·f/cm²) to about 3 kg·f/cm² by a pressure roller RL.

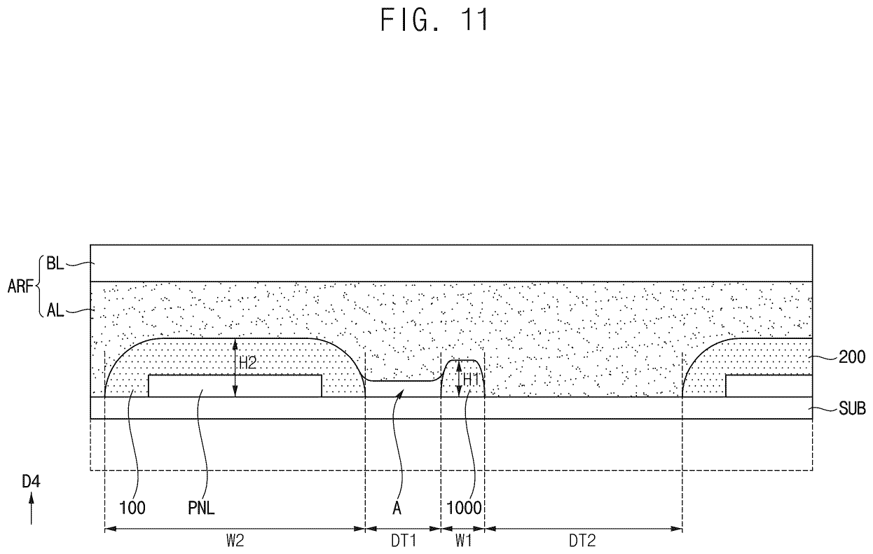

Referring to FIG. 11, a substrate SUB may be formed by etching the preliminary substrate SUB′. In an embodiment, the preliminary substrate SUB′ may be wet etched using a hydrofluoric acid. In an embodiment, for example, the preliminary substrate SUB′ on which the display panels PNL and the protective films PF are formed may be exposed to the hydrofluoric acid solution. During the wet etching process, the acid-resistant film ARF may protect the display panels PNL and the protective films PF from the hydrofluoric acid.

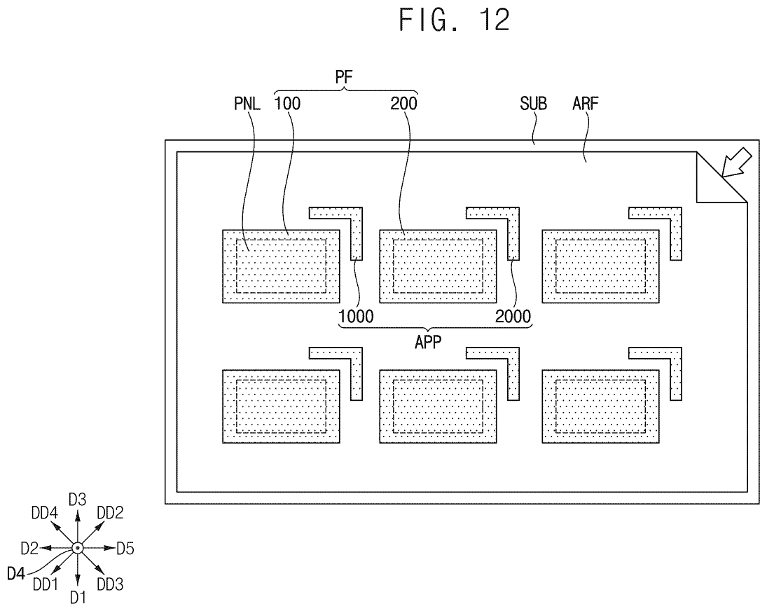

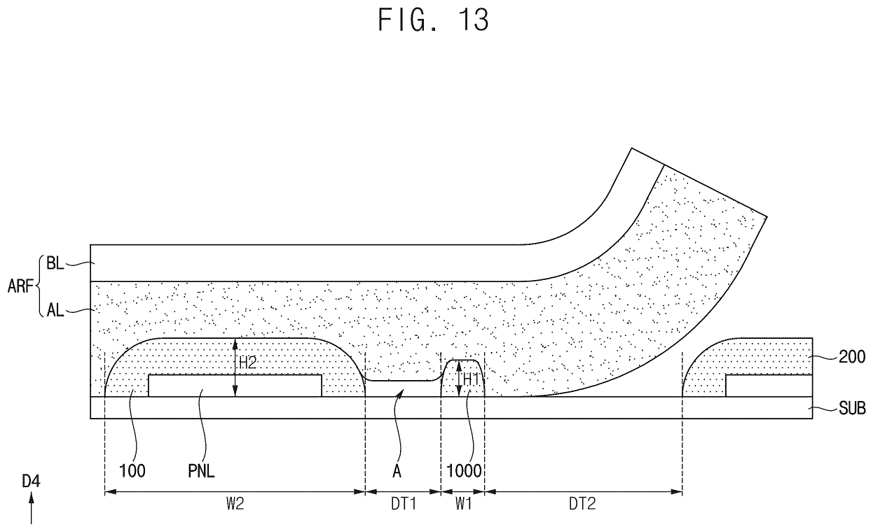

Referring to FIGS. 12, 13, and 14, the acid-resistant film ARF may be removed along the first diagonal direction DD1. In an embodiment, as shown in FIG. 13, the adhesive layer AL may not be applied or less applied to an end of each of the protective films PF, where the end of each of the protective films PF is an end thereof adjacent to a corresponding one of the anti-peeling patterns APP. In an embodiment, as shown in FIG. 13, the adhesive layer AL may not be applied or less applied to an end area A adjacent to each of the protective films PF adjacent to each of the anti-peeling patterns APP. Here, the end area A may be an area of the substrate SUB between ends of a protective film PF and an anti-peeling pattern APP adjacent to each other. Accordingly, while the acid-resistant film ARF is removed, the protective films PF may not be removed and may remain. In addition, while the acid-resistant film ARF is removed, the first anti-peeling pattern 1000 may be removed by being detached (or separated) from the substrate.

Referring to FIGS. 15 and 19, a stain line LN may be formed at a location where the anti-peeling patterns APP were formed. In an embodiment, for example, as the monomers in the resin forming the anti-peeling patterns APP are cured into a polymer, a difference in internal stress between a center and an end portion of the anti-peeling patterns APP may be induced. Accordingly, after the anti-peeling patterns APP are removed, a stain line LN may be formed at a location where the anti-peeling patterns APP were formed.

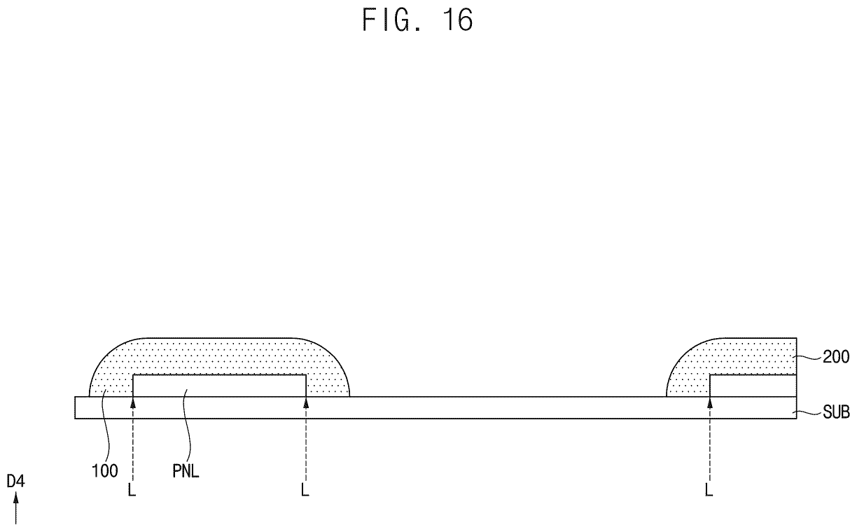

Referring to FIG. 16, a laser L may be radiated between the display panels PNL. As the laser L is radiated, the substrate SUB may be smoothly cut with the laser L as a boundary. In an embodiment, the laser L may be radiated to the rear surface of the substrate SUB, but the invention is not limited thereto. In an embodiment, for example, the laser L radiation process may be omitted.

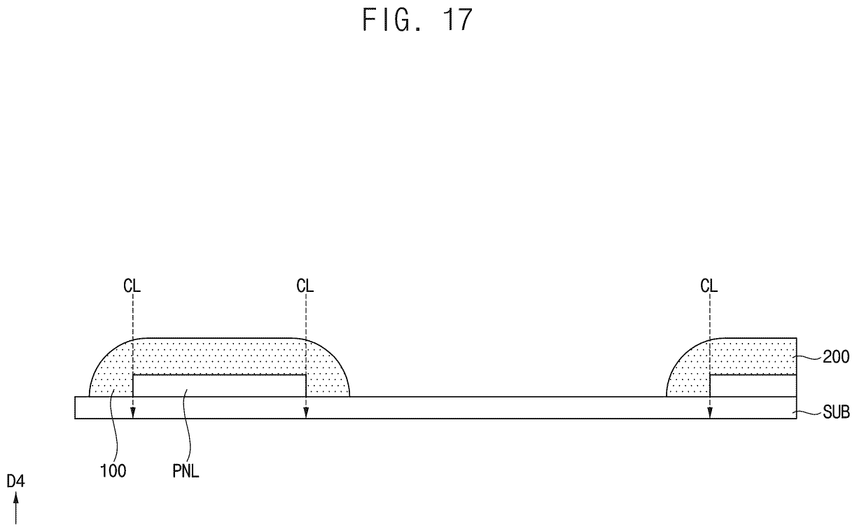

Referring to FIG. 17, the substrate SUB may be cut along an area irradiated with the laser L.

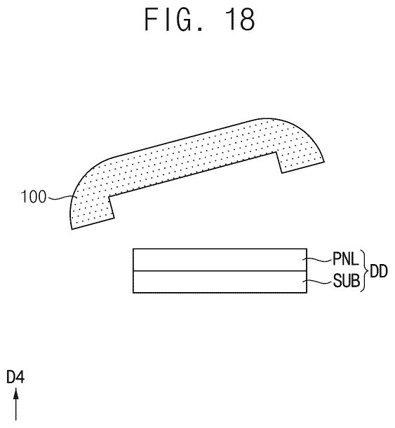

Referring to FIG. 18, the first protective film 100 may be removed from the display panels PNL, and a display device DD including the substrate SUB and the display panel PNL may be manufactured.

In an embodiment of the method of manufacturing the display device DD, the anti-peeling patterns APP may be formed together with the protective films PF. Accordingly, a process of forming the anti-peeling patterns APP may be simplified. In such an embodiment, the anti-peeling patterns APP may be removed along with the acid-resistant film ARF. Accordingly, a process of removing the anti-peeling patterns APP may be simplified.

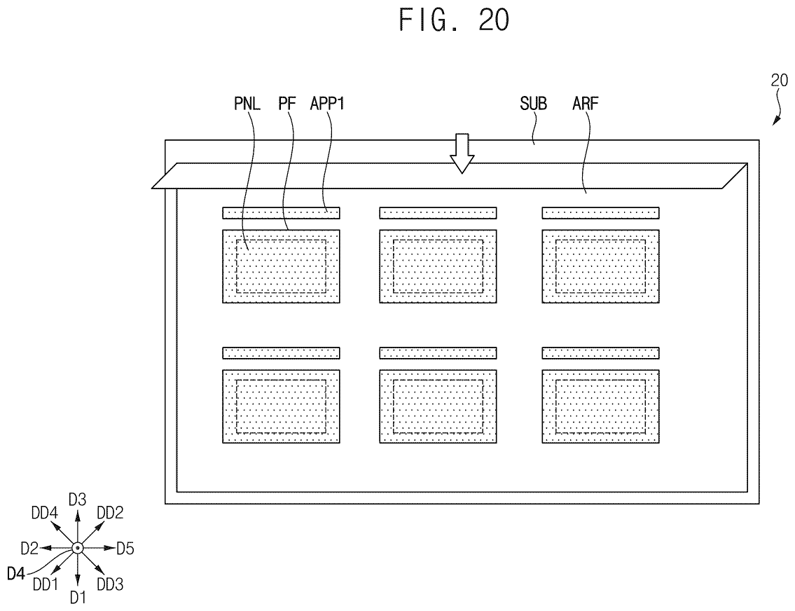

FIG. 20 is a plan view illustrating a mother substrate for a display panel according to an alternative embodiment of the invention.

Referring to FIG. 20, a mother substrate 20 for a display panel according to an embodiment of the invention may include a substrate SUB, display panels PNL, protective films PF, anti-peeling patterns APP1, and an acid-resistant film ARF. In such an embodiment, the mother substrate 20 for the display panel may be substantially the same as the mother substrate 10 for the display panel described above with reference to FIG. 1 except for the anti-peeling patterns APP1.

In an embodiment, the protective films PF may be arranged along the first direction D1 and the second direction D2 when viewed in a plan view or when viewed in the fourth direction D4. In addition, the protective films PF may have a short side in the first direction D1 and a long side in the second direction D2.

In an embodiment, the acid-resistant film ARF may be removed along the first direction D1. In this case, the anti-peeling patterns APP1 may respectively be adjacent to the protective films PF in a third direction D3 opposite to the first direction D1. In an embodiment, for example, each of the anti-peeling patterns APP1 may be adjacent to a long side of each of the protective films PF and may have a same length as the long side.

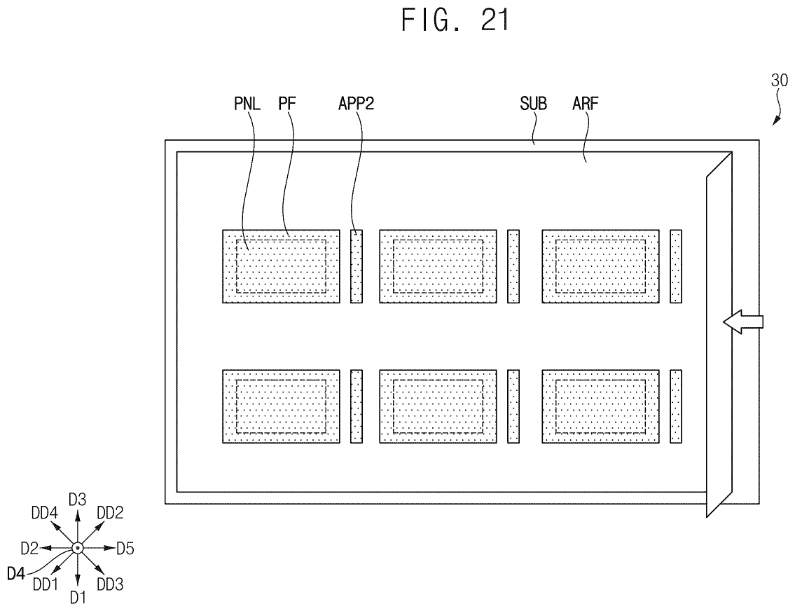

FIG. 21 is a plan view illustrating a mother substrate for a display panel according to another alternative embodiment of the invention.

Referring to FIG. 21, a mother substrate 30 for a display panel according to an embodiment of the invention may include a substrate SUB, display panels PNL, protective films PF, anti-peeling patterns APP2, and an acid-resistant film ARF. In such an embodiment, the mother substrate 30 for the display panel may be substantially the same as the mother substrate 10 for the display panel described above with reference to FIG. 1 except for the anti-peeling patterns APP2.

In an embodiment, the protective films PF may be arranged along the first direction D1 and the second direction D2 when viewed in a plan view or when viewed in the fourth direction D4. In addition, the protective films PF may have a short side in the first direction D1 and a long side in the second direction D2.

In an embodiment, the acid-resistant film ARF may be removed along the second direction D2. In this case, the anti-peeling patterns APP2 may be adjacent to the protective films PF in a fifth direction D5 opposite to the second direction D2. In an embodiment, for example, each of the anti-peeling patterns APP2 may be adjacent to a short side of each of the protective films PF and may have a same length as the short side.

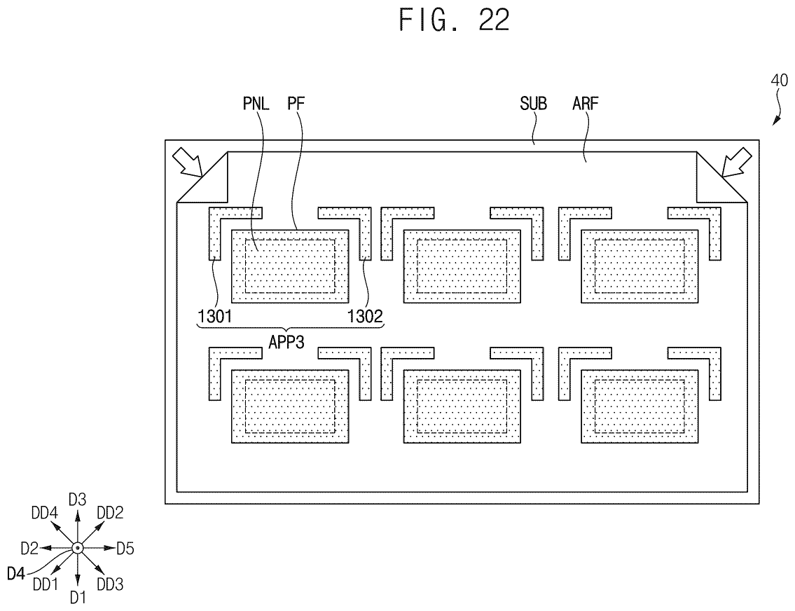

FIG. 22 is a plan view illustrating a mother substrate for a display panel according to still another alternative embodiment of the invention.

Referring to FIG. 22, a mother substrate 40 for a display panel according to an embodiment of the invention may include a substrate SUB, display panels PNL, protective films PF, anti-peeling patterns APP3, and an acid-resistant film ARF. In such an embodiment, the mother substrate 40 for the display panel may be substantially the same as the mother substrate 10 for the display panel described above with reference to FIG. 1 except for the anti-peeling patterns APP3.

In an embodiment, the protective films PF may be arranged along the first direction D1 and the second direction D2 when viewed in a plan view or when viewed in the fourth direction D4.

In an embodiment, a third diagonal direction DD3 symmetrical to the first diagonal direction DD1 with the first direction D1 as an axis of symmetry, and a fourth diagonal direction DD4 opposite to the third diagonal direction DD3 may be defined. The acid-resistant film ARF may be removed along the first diagonal direction DD1 and the third diagonal direction DD3. In this case, the anti-peeling patterns APP3 may be adjacent to the protective films PF in the second diagonal direction DD2 and the fourth diagonal direction DD4. In an embodiment, for example, the anti-peeling patterns APP3 may include a first anti-peeling pattern 1301 and a second anti-peeling pattern 1302, the first anti-peeling pattern 1301 may be adjacent to the protective films in the fourth diagonal direction DD4, and the second anti-peeling pattern 1302 may be adjacent to the protective films in the second diagonal direction DD2.

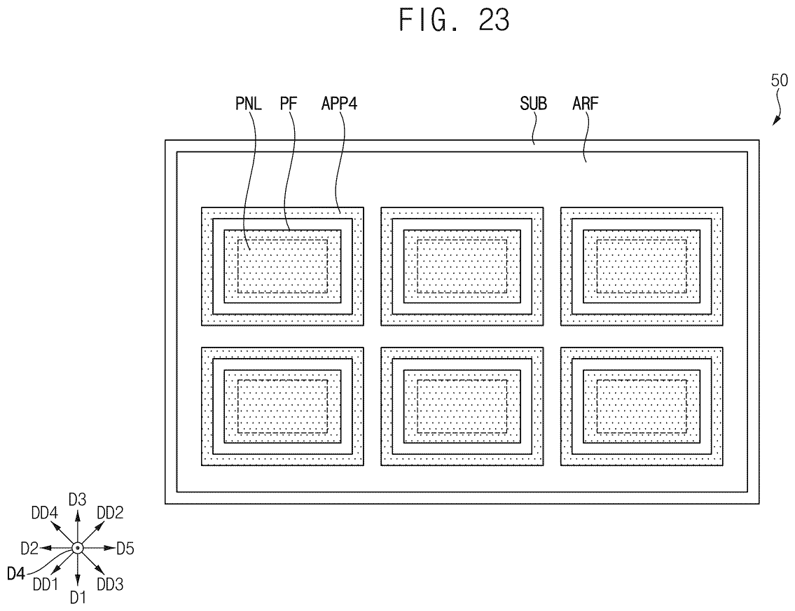

FIG. 23 is a plan view illustrating a mother substrate for a display panel according to still another alternative embodiment of the invention.

Referring to FIG. 23, a mother substrate 50 for a display panel according to an embodiment of the invention may include a substrate SUB, display panels PNL, protective films PF, anti-peeling patterns APP4, and an acid-resistant film ARF. In such an embodiment, the mother substrate 50 for the display panel may be substantially the same as the mother substrate 10 for the display panel described above with reference to FIG. 1 except for the anti-peeling patterns APP4.

In an embodiment, the protective films PF may be arranged along the first direction D1 and the second direction D2 when viewed in a plan view or when viewed in the fourth direction D4.

In an embodiment, the anti-peeling patterns APP4 may be adjacent to the protective films PF, respectively, and each of the anti-peeling patterns APP4 may surround a corresponding one of the protective films PF. Accordingly, regardless of the direction in which the acid-resistant film ARF is removed, the anti-peeling patterns APP4 may effectively prevent the protective films PF from being removed while the acid-resistant film ARF is removed.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mother substrate for a display panel, the mother substrate comprising:
display panels disposed on a substrate;
protective films disposed on the display panels and covering the display panels, respectively; and
anti-peeling patterns disposed on the substrate and adjacent to the protective films, respectively.

2. The mother substrate of claim 1, wherein
the protective films include a first protective film and a second protective film adjacent to the first protective film,
the anti-peeling patterns include a first anti-peeling pattern and a second anti-peeling pattern,
the first anti-peeling pattern is adjacent to the first protective film and is disposed between the first protective film and the second protective film, and
the second anti-peeling pattern is adjacent to the second protective film.

3. The mother substrate of claim 2, wherein a first distance between the first anti-peeling pattern and a first protective film is less than a half of a distance between the first protective film and the second protective film.

4. The mother substrate of claim 3, wherein the first distance is less than a second distance between the first anti-peeling pattern and the second protective film.

5. The mother substrate of claim 4, wherein
the first distance is in a range of about 200 μm to 1000 μm, and
the second distance is greater than about 1000 μm.

6. The mother substrate of claim 1, wherein a first height of each of the anti-peeling patterns is in a range of about 30% to about 100% of a second height of each of the protective films.

7. The mother substrate of claim 6, wherein the first height is in a range of about 30 μm to 100 μm.

8. The mother substrate of claim 1, wherein a width of each of the anti-peeling patterns is in a range of about 3 mm to 10 mm.

9. The mother substrate of claim 1, further comprising:
an acid-resistant film disposed on the substrate and covering the protective films and the anti-peeling patterns.

10. The mother substrate of claim 9, wherein the acid-resistant film includes:
a base layer; and
an adhesive layer disposed under the base layer and contacting the protective films and the anti-peeling patterns, and
wherein the adhesive layer is not applied to an end of each of the protective films, wherein the end of each of the protective films is an end thereof adjacent to a corresponding one of the anti-peeling patterns.

11. The mother substrate of claim 9, wherein
the protective films are arranged along a first direction and a second direction perpendicular to the first direction when viewed in a thickness direction of the substrate,
the acid-resistant film is removed along the first direction, and
the anti-peeling patterns are adjacent to the protective films in a third direction opposite to the first direction.

12. The mother substrate of claim 9, wherein
the protective films are arranged along a first direction and a second direction perpendicular to the first direction when viewed in a thickness direction of the substrate,
the acid-resistant film is removed along a first diagonal direction between the first direction and the second direction, and
the anti-peeling patterns are adjacent to the protective films in a second diagonal direction opposite to the first diagonal direction.

13. The mother substrate of claim 12, wherein each of the anti-peeling patterns includes:
a first portion extending in the first direction; and
a second portion extending in the second direction and connected to the first portion.

14. The mother substrate of claim 9, wherein
the protective films are arranged along a first direction and a second direction perpendicular to the first direction when viewed in a thickness direction of the substrate,
the acid-resistant film is removed along a first diagonal direction and a third diagonal direction, wherein the first diagonal direction is between the first direction and the second direction, and the third diagonal direction is symmetrical to the first diagonal direction with the first direction as an axis of symmetry, and
the anti-peeling patterns are adjacent to the protective films in a second diagonal direction and a fourth diagonal direction, wherein the second diagonal direction is opposite to the first diagonal direction, and the fourth diagonal direction is opposite to the third diagonal direction.

15. The mother substrate of claim 9, wherein
the protective films are arranged along a first direction and a second direction perpendicular to the first direction when viewed in a thickness direction of the substrate, and
the anti-peeling patterns is adjacent to the protective films, respectively, and each of the anti-peeling patterns surrounds a corresponding one of the protective films.

16. The mother substrate of claim 1, wherein the anti-peeling patterns include a same material as the protective films.

17. A method of manufacturing a display device, the method comprising:
forming display panels on a preliminary substrate;
forming protective films covering the display panels on the preliminary substrate; and
forming anti-peeling patterns adjacent to the protective films, respectively, on the preliminary substrate.

18. The method of claim 17, wherein the protective films and the anti-peeling patterns are formed during a same process using a same material.

19. The method of claim 17, further comprising:
adhering an acid-resistant film on the preliminary substrate to cover the protective films and the anti-peeling patterns;
forming a substrate by etching the preliminary substrate;
removing the acid-resistant film; and
removing the anti-peeling patterns.

20. The method of claim 19, wherein the anti-peeling patterns are removed together with the acid-resistant film.
